(19) United States
(12) Patent Application Publication
(10) Pub. No.: US 2025/0193971 A1
(43) Pub. Date: Jun. 12, 2025

(54) CERAMIC SUSCEPTOR

(71) Applicant: NGK INSULATORS, LTD., Nagoya-City (JP)

(72) Inventor: Naoki YOSHITAKE, Nagoya-Shi (JP)

(73) Assignee: NGK INSULATORS, LTD., Nagoya-City (JP)

(21) Appl. No.: 18/905,235

(22) Filed: Oct. 3, 2024

Related U.S. Application Data
(63) Continuation of application No. PCT/JP2023/043646, filed on Dec. 6, 2023.

(51) Int. Cl. H05B 3/28; H01L 21/67; H01L 21/683; H01L 21/687

(52) U.S. Cl. CPC H05B 3/283; H01L 21/67103; H01L 21/67248; H01L 21/68785; H01L 21/6833

(57) ABSTRACT

There is provided a ceramic susceptor including: a disk-shaped ceramic plate bonded body including an upper ceramic plate and a lower ceramic plate bonded to each other at a bonding surface, the disk-shaped ceramic plate bonded body having a first surface opposite the bonding surface of the upper ceramic plate and a second surface opposite the bonding surface of the lower ceramic plate; at least one internal electrode selected from the group consisting of an RF electrode and an ESC electrode, the internal electrode being embedded in the upper ceramic plate parallel to the first surface; a first heater circuit embedded in the lower ceramic plate parallel to the first surface; and a thermocouple insertion groove provided in the bonding surface side of the upper ceramic plate or the lower ceramic plate, the thermocouple insertion groove forming a thermocouple insertion path together with the bonding surface.

### CROSS-REFERENCE TO RELATED APPLICATION

This application is a continuation application of PCT/JP2023/043646 filed Dec. 6, 2023, the entire contents of which are incorporated herein by reference.

### BACKGROUND OF THE INVENTION

### 1. Field of the Invention

The present disclosure relates to a ceramic susceptor.

### 2. Description of the Related Art

In a film deposition apparatus for a semiconductor manufacturing process, a ceramic heater is used as a support stage for uniformly controlling the temperature of a wafer. As such ceramic heaters, ceramic heaters are widely used, each of which includes a ceramic plate for a wafer being placed, and a cylindrical ceramic shaft attached to the ceramic plate. The ceramic plate generally has a configuration in which internal electrodes such as a heater electrode, an RF electrode, and an electrostatic chuck (ESC) electrode are embedded inside a ceramic base made of aluminum nitride (AlN) or the like, which has excellent heat resistance and corrosion resistance.

As the ceramic heater, a ceramic heater is known that is provided with a thermocouple insertion path for inserting a thermocouple for controlling the outer circumference temperature.

Patent Literature 1 (JP7181314B) discloses a ceramic heater including: a disk-shaped ceramic plate having a wafer placement surface; an outer circumferential resistance heating element incorporated in the ceramic plate and provided so as to turn back at a plurality of turn-back portions in an annular outer circumferential zone; an outer circumferential thermocouple that measures the temperature of the outer circumferential zone with a temperature measurement portion at a tip of the outer circumferential thermocouple. When the ceramic plate is viewed from the wafer placement surface, this temperature measurement portion is arranged in the outer circumferential zone excluding a part where the turn-back portions of the outer circumferential resistance heating element face each other. Inside the ceramic plate, a thermocouple path is provided parallel to the wafer placement surface. This thermocouple path is configured to extend from an insertion opening that opens in the center portion of the ceramic plate on the surface opposite the wafer placement surface to a terminal position just before the outer circumferential surface of the ceramic plate.

Patent Literature 2 (JP2021-174586A) discloses a ceramic heater including: a disk-shaped ceramic base having a wafer placement surface; a resistance heating element embedded in the ceramic base; a cylindrical shaft supporting the ceramic base from a lower surface of the ceramic base; a thermocouple passage; and a thermocouple insertion hole communicating with the thermocouple passage. The thermocouple passage is provided between the resistance heating element and the wafer placement surface, and is provided so as to extend from a starting position inside the ceramic base on the center side to a terminal position on the outer circumferential side. The thermocouple passage is provided so that an opening, located on the lower surface of the ceramic base in a shaft inner region surrounded by the cylindrical shaft, communicates with the thermocouple passage.

### CITATION LIST

### Patent Literature

Patent Literature 1: JP7181314B

Patent Literature 2: JP2021-174586A

### SUMMARY OF THE INVENTION

However, when an attempt is made to further incorporate an internal electrode such as an ESC electrode or an RF electrode into a ceramic heater having a thermocouple insertion path to enhance the function of the ceramic heater, the presence of the thermocouple insertion path or the thermocouple inserted therein may have an undesirable influence on the attraction performance or plasma characteristics provided by the ESC electrode or the RF electrode. As a result, the ceramic heater may not be able to maximize its desired performance.

The inventors have now discovered that the influence on the attraction performance or plasma characteristics can be reduced by arranging the thermocouple insertion groove at a depth between the internal electrode and the first heater circuit in the thickness direction of the ceramic plate.

Therefore, an object of the present invention is to provide a ceramic susceptor that can reduce an influence on attraction performance or plasma characteristics while incorporating not only a heater circuit and a thermocouple insertion path but also internal electrodes such as an ESC electrode and an RF electrode.

The present disclosure provides the following aspects.

[Aspect 1]

A ceramic susceptor comprising:
a disk-shaped ceramic plate bonded body including an upper ceramic plate and a lower ceramic plate bonded to each other at a bonding surface, the disk-shaped ceramic plate bonded body having a first surface opposite the bonding surface of the upper ceramic plate and a second surface opposite the bonding surface of the lower ceramic plate;
at least one internal electrode selected from the group consisting of an RF electrode and an ESC electrode, the internal electrode being embedded in the upper ceramic plate parallel to the first surface;
a first heater circuit embedded in the lower ceramic plate parallel to the first surface; and
a thermocouple insertion groove provided in the bonding surface side of the upper ceramic plate or the lower ceramic plate, the thermocouple insertion groove forming a thermocouple insertion path together with the bonding surface,
whereby the thermocouple insertion groove is arranged at a depth between the internal electrode and the first heater circuit in a thickness direction of the ceramic plate bonded body.

[Aspect 2]

The ceramic susceptor according to aspect 1, further comprising a second heater circuit embedded in the upper ceramic plate parallel to the first surface, whereby the thermocouple insertion groove is arranged at a depth between the first heater circuit and the second heater circuit in the thickness direction of the ceramic plate bonded body.

[Aspect 3]

The ceramic susceptor according to aspect 2, wherein the second heater circuit is provided at a depth farther from the first surface than the internal electrode.

[Aspect 4]

The ceramic susceptor according to aspect 2 or 3, wherein when the ceramic plate bonded body is viewed in a plane, the ceramic plate bonded body includes an inner zone defined as a circular region within a predetermined distance from a center of the ceramic plate bonded body, and an outer zone defined as an annular region outside the inner zone, and
wherein the first heater circuit is arranged in the outer zone, and the second heater circuit is arranged in the inner zone.

[Aspect 5]

The ceramic susceptor according to aspect 4, further comprising a jumper embedded in the inner zone in the lower ceramic plate and connected to the first heater circuit, wherein power is suppliable to the first heater circuit through the jumper via a power supply rod, the power supply rod having one end connected to the jumper and another end extending from the second surface to an outside of the ceramic plate bonded body.

[Aspect 6]

The ceramic susceptor according to aspect 4 or 5, further comprising a thermocouple insertion hole composed of a vertical hole that penetrates the lower ceramic plate from the inner zone of the second surface to reach the upper ceramic plate.

[Aspect 7]

The ceramic susceptor according to aspect 6, wherein the thermocouple insertion hole reaches a depth closer to the first surface than the second heater circuit.

[Aspect 8]

The ceramic susceptor according to any one of aspects 1 to 7, further comprising a cylindrical ceramic shaft attached to the second surface of the ceramic plate bonded body.

[Aspect 9]

The ceramic susceptor according to any one of aspects 1 to 8, further comprising a first thermocouple for an outer zone, the first thermocouple being inserted into the thermocouple insertion path.

[Aspect 10]

The ceramic susceptor according to any one of aspects 6 to 9, further comprising a second thermocouple for the inner zone, the second thermocouple being inserted into the thermocouple insertion hole.

[Aspect 11]

The ceramic susceptor according to aspect 10, wherein the second thermocouple reaches a depth closer to the first surface than the first thermocouple.

### BRIEF DESCRIPTION OF THE DRAWINGS

FIG. 1 is a schematic cross-sectional view showing an example of a ceramic susceptor according to the present invention.

FIG. 2 is a schematic cross-sectional view showing another example of a ceramic susceptor according to the present invention.

FIG. 3 is a schematic plan view of the ceramic susceptor as shown in FIG. 2 as viewed from a ceramic shaft side.

### DESCRIPTION OF EMBODIMENT

A ceramic susceptor according to the present invention is a table made of ceramic for supporting a wafer, used in a film deposition apparatus or an etching apparatus, particularly a film deposition apparatus or an etching apparatus for a semiconductor manufacturing process. For example, the ceramic susceptor according to the present invention may be a ceramic heater for a semiconductor film deposition apparatus, or an electrostatic chuck for a semiconductor etching apparatus. Alternatively, the ceramic susceptor may be an electrostatic chuck heater that combines a heater function and an electrostatic chuck function. Typical examples of film deposition apparatuses include CVD (chemical vapor deposition) apparatuses (e.g., thermal CVD apparatuses, plasma CVD apparatuses, photo CVD apparatuses, and MOCVD apparatuses), and PVD (physical vapor deposition) apparatuses.

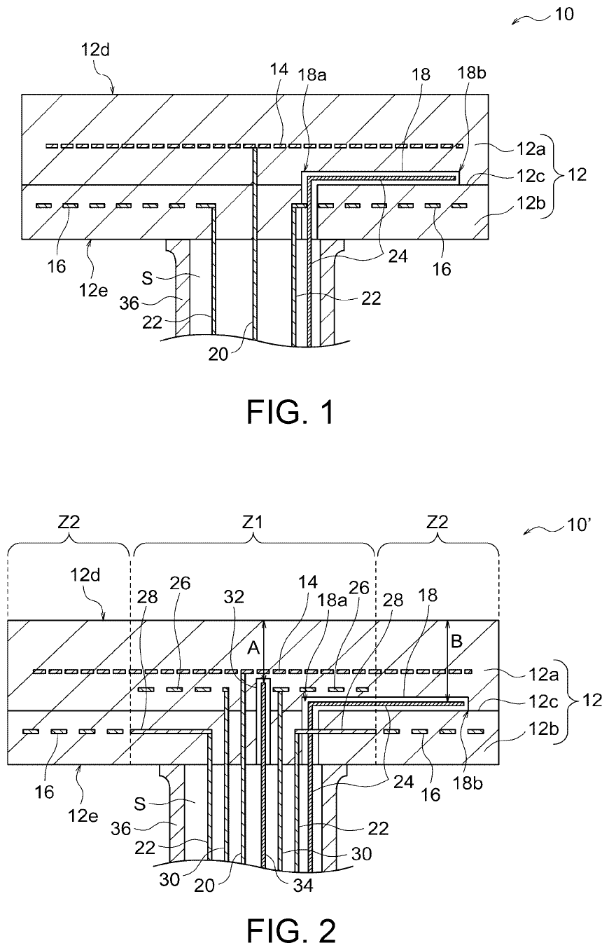

FIG. 1 shows an example of a ceramic susceptor. The ceramic susceptor 10 shown in FIG. 1 includes a ceramic plate bonded body 12, an internal electrode 14, a first heater circuit 16, and a thermocouple insertion groove 18. The ceramic plate bonded body 12 is disk-shaped and includes an upper ceramic plate 12a and a lower ceramic plate 12b that are bonded to each other at a bonding surface 12c. The ceramic plate bonded body 12 has a first surface 12d opposite the bonding surface 12c of the upper ceramic plate 12a and a second surface 12e opposite the bonding surface 12c of the lower ceramic plate 12b. The internal electrode 14 is at least one selected from the group consisting of an RF electrode and an ESC electrode, and is embedded in the upper ceramic plate 12a parallel to the first surface 12d. The first heater circuit 16 is embedded in the lower ceramic plate 12b parallel to the first surface 12d. The thermocouple insertion groove 18 is provided on the bonding surface 12c side of the upper ceramic plate 12a or the lower ceramic plate 12b, and configures a thermocouple insertion path together with the bonding surface 12c. As a result, the thermocouple insertion groove 18 is arranged at a depth between the internal electrode 14 and the first heater circuit 16 in the thickness direction of the ceramic plate bonded body 12. Arranging the thermocouple insertion groove 18 in this manner makes it possible to provide a ceramic susceptor 10 that can reduce the influence on attraction performance or plasma characteristics while incorporating not only the heater circuit and thermocouple insertion path but also the internal electrode 14 such as an ESC electrode or an RF electrode.

As mentioned above, when an attempt is made to further incorporate an internal electrode such as an ESC electrode or an RF electrode into a ceramic heater having a thermocouple insertion path to enhance the function of the ceramic heater, the presence of the thermocouple insertion path or the thermocouple inserted therein may have an undesirable influence on attraction performance or plasma characteristics provided by the ESC electrode or the RF electrode. As a result, the ceramic heater may not be able to maximize its desired performance. This problem is successfully solved by the configuration of the present invention. In other words, the thermocouple insertion groove 18 is arranged at a depth between the internal electrode 14 and the first heater circuit 16 in the thickness direction of the ceramic plate bonded body 12, and this makes a configuration such that there are no other components (such as the first heater circuit 16, the second heater circuit 26 described later with reference to FIG. 2, the thermocouple insertion groove 18, and the first thermocouple 24) that may become obstacles, between the first surface 12d of the ceramic plate bonded body 12 and the internal electrode 14. Therefore, the attraction performance provided by the ESC electrode and/or the plasma characteristics provided by the RF electrode can be maximized without being affected by such other components. In addition, as a secondary effect, the above arrangement can ensure a long separation distance between the internal electrode 14 and the first heater circuit 16. This can reduce leakage current that may flow from the internal electrode 14 to the first heater circuit 16 due to the potential difference between the internal electrode 14 and the first heater circuit 16. In other words, if the separation distance between the internal electrode 14 and the first heater circuit 16 is long, the resistance increases accordingly, and the leakage current that may flow between them can be further reduced. Furthermore, in the above arrangement, the thermocouple insertion groove 18 is arranged at a depth closer to the first surface 12d than the first heater circuit 16. Therefore, the above arrangement advantageously makes it possible to reduce the discrepancy between the temperature of the first surface 12d and the temperature read by the first thermocouple 24 in the thermocouple insertion groove 18.

The ceramic plate bonded body 12 includes the upper ceramic plate 12a and the lower ceramic plate 12b bonded to each other at the bonding surface 12c. The upper ceramic plate 12a and the lower ceramic plate 12b may be made of materials having the same physical properties, or may be made of materials having different physical properties (e.g., volume resistance and thermal expansion coefficient). In the latter case, for example, the volume resistance of the upper ceramic plate 12a may be relatively higher than that of the lower ceramic plate 12b, or the volume resistance of the lower ceramic plate 12b may be relatively higher than that of the upper ceramic plate 12a. In any case, each of the upper ceramic plate 12a and the lower ceramic plate 12b is not particularly limited except for the arrangement of the first heater circuit 16, the second heater circuit 26 described later, the thermocouple insertion groove 18, and the thermocouple insertion hole described later, and may have the same configuration as a ceramic plate employed in a known ceramic susceptor or ceramic heater. Therefore, the upper ceramic plate 12a and the lower ceramic plate 12b preferably contain aluminum nitride or aluminum oxide, more preferably aluminum nitride, from the viewpoints of excellent thermal conductivity, high electrical insulation, and thermal expansion characteristics close to those of silicon.

The internal electrode 14 is an electrode embedded in the upper ceramic plate 12a parallel to the first surface, and includes at least one selected from the group consisting of an RF electrode and an ESC electrode. Applying a high frequency to the RF electrode enables film deposition by a plasma CVD process. ESC electrode is an abbreviation for electrostatic chuck (ESC) electrode, and is also called an electrostatic electrode. The ESC electrode is preferably a circular thin-layer electrode with a diameter slightly smaller than that of the ceramic plate bonded body 12, and may be, for example, a mesh electrode formed by weaving thin metal wires into a net shape to make a sheet shape. The ESC electrode may be used as a plasma electrode. In other words, applying a high frequency to the ESC electrode also enables using the ESC electrode as an RF electrode, and performing film deposition through a plasma CVD process. The internal electrode 14 is connected to a terminal rod 20, and the terminal rod 20 is connected to an external power source (not shown). If the internal electrode 14 is an ESC electrode, when a voltage is applied by an external power source to the ESC electrode, the ESC electrode chucks a wafer placed on the surface of the ceramic plate bonded body 12 by the Johnsen-Rahbek force.

The first heater circuit 16 is embedded in the lower ceramic plate 12b parallel to the first surface 12d. The first heater circuit 16 is not particularly limited. However, the first heater circuit 16 may be, for example, a conductive coil wired in a single stroke over the entire surface or a predetermined region (typically an outer zone Z2 described later with reference to FIG. 2) of the lower ceramic plate 12b. Power supply rods 22 are respectively connected to opposite ends of the first heater circuit 16 for power supply, and the power supply rods 22 are connected to a heater power source (not shown). When power is supplied from the heater power source, the first heater circuit 16 generates heat and heats the wafer placed on the surface of the first surface 12d. The first heater circuit 16 is not limited to a coil, and may be, for example, a ribbon (an elongated, thin plate), a mesh, or a print.

The thermocouple insertion groove 18 is a groove that configures a thermocouple insertion path together with the bonding surface 12c, and is provided on the bonding surface 12c side of the upper ceramic plate 12a or the lower ceramic plate 12b. The presence of thermocouple insertion groove 18 or thermocouple insertion path allows a first thermocouple 24 to be inserted or accommodated therein. This allows for measuring the temperature at a predetermined position (typically an outer circumferential portion such as an outer zone Z2 described later with reference to FIG. 2) of the ceramic plate bonded body 12 or the internal electrode 14. The thermocouple insertion groove 18 is preferably provided in the upper ceramic plate 12a as shown in FIG. 1, but may be provided in the lower ceramic plate 12b. The thermocouple insertion groove 18 is preferably provided linearly from a thermocouple insertion opening 18a, which is a vertical hole formed in the second surface 12e, to a thermocouple insertion path end 18b. The thermocouple insertion path end 18b is preferably a closed end for accurate temperature measurement.

FIG. 2 shows a ceramic susceptor 10′ according to a preferred aspect of the present invention. In addition to the above-described configuration, this ceramic susceptor 10′ further includes a second heater circuit 26. The second heater circuit 26 is embedded in the upper ceramic plate 12a parallel to the first surface 12d. Thereby, the thermocouple insertion groove 18 is arranged at a depth between the first heater circuit 16 and the second heater circuit 26 in the thickness direction of the ceramic plate bonded body 12. In this case, the second heater circuit 26 is preferably provided at a depth farther from the first surface 12d than the internal electrode 14. This makes a configuration such that there are no other components (such as the first heater circuit 16, the second heater circuit 26, the thermocouple insertion groove 18, etc.) that may become an obstacle, between the first surface 12d and the internal electrode 14 of the ceramic plate bonded body 12. Therefore, the attraction performance provided by the ESC electrode and/or the plasma characteristics provided by the RF electrode can be maximized without being affected by such other components. The second heater circuit 26 is also not particularly limited. However, the second heater circuit 26 may be, for example, a conductive coil wired in a single stroke over a predetermined region of the upper ceramic plate 12a (preferably the inner zone Z1 described later). Power supply rods 30 are connected to opposite ends of the second heater circuit 26 for power supply, and the power supply rods 30 are connected to a heater power source (not shown). When power is supplied from the heater power source, the second heater circuit 26, together with the first heater circuit 16, generates heat and heats the wafer placed on the surface of the first surface 12d. The second heater circuit 26 is not limited to a coil, and may be, for example, a ribbon (an elongated, thin plate), a mesh, or a print.

In the ceramic susceptor 10′, the ceramic plate bonded body 12 may include an inner zone Z1 and an outer zone Z2. When the ceramic plate bonded body 12 is viewed in a plane, the inner zone Z1 is defined as a circular region within a predetermined distance from the center of the ceramic plate bonded body 12, while the outer zone Z2 is defined as an annular region outside the inner zone Z1. In this aspect, it is preferable that the first heater circuit 16 be arranged in the outer zone Z2, and the second heater circuit 26 be arranged in the inner zone Z1. This allows the temperature of the inner zone Z1 and the outer zone Z2 to be adjusted separately by the first heater circuit 16 and the second heater circuit 26, respectively. This makes it possible to heat the ceramic plate bonded body 12 with a desired temperature distribution profile.

As shown in FIG. 2, the ceramic susceptor 10′ is preferably further includes jumpers 28. The jumpers 28 are embedded in the inner zone Z1 in the lower ceramic plate 12b and are provided so as to be connected to the first heater circuit 16. In this case, each power supply rod 22 is provided so that one end is connected to the jumper 28 and the other end extends from the second surface 12e to the outside of the ceramic plate bonded body 12. In this way, power can be supplied to the first heater circuit 16 via the power supply rods 22 and the jumpers 28.

As shown in FIG. 2, the ceramic susceptor 10′ is preferably further includes a thermocouple insertion hole 32. The thermocouple insertion hole 32 is a vertical hole that penetrates the lower ceramic plate 12b from the inner zone Z1 of the second surface 12e to reach the upper ceramic plate 12a. Inserting a second thermocouple 34 into this thermocouple insertion hole 32 makes it possible to measure the temperature in the inner zone Z1 of the ceramic plate bonded body 12 or the internal electrode 14. In this case, it is preferable that the thermocouple insertion hole 32 reaches a depth closer to the first surface 12d than the second heater circuit 26. This can reduce the discrepancy between the temperature of the first surface 12d and the temperature read by the second thermocouple 34 in the thermocouple insertion hole 32.

The ceramic susceptor 10′ preferably includes a first thermocouple 24 for the outer zone Z2 inserted into the thermocouple insertion path (or the thermocouple insertion groove 18). The ceramic susceptor 10′ also preferably includes a second thermocouple 34 for the inner zone Z1 inserted into the thermocouple insertion hole 32. Temperature measuring devices (not shown) can be connected to the distal ends of the first thermocouple 24 and the second thermocouple 34.

The second thermocouple 34 preferably reaches a depth closer to the first surface 12d than the first thermocouple 24. Specifically, the ratio of a separation distance B to a separation distance A (i.e., the value of B/A) is preferably 1.4 to 3.0, the separation distance B being a distance between the first thermocouple 24 and the first surface 12d, the separation distance A being a distance between the proximal end (the end closer to the first surface 12d) of the second thermocouple 34 and the first surface 12d. In this aspect, the separation distance A between the proximal end of the second thermocouple 34 and the first surface 12d is preferably 4 to 6 mm. The thickness of the ceramic plate bonded body 12 is preferably 20 to 35 mm. This aspect allows the second thermocouple 34 to accurately measure the temperature of the inner zone Z1. At the same time, this aspect allows for more effectively reducing the undesirable influence, which is given to the attraction performance or plasma characteristics by the thermocouple insertion groove 18 for the first thermocouple 24 or the first thermocouple 24 inserted therein, the attraction performance or plasma characteristics being provided by the internal electrode 14, which is an ESC electrode or an RF electrode, the thermocouple insertion groove 18 having a larger groove area than the cross-sectional area of the thermocouple insertion hole 32 for the second thermocouple 34.

Optionally, a cylindrical ceramic shaft 36 may be attached (preferably concentrically) to the second surface 12e of the ceramic plate bonded body 12. The ceramic shaft 36 is a cylindrical member with an internal space S, and may be configured similarly to a ceramic shaft employed in a known ceramic susceptor or ceramic heater. The internal space S is configured to allow the terminal rod 20, the power supply rods 22, the power supply rods 30 (if present), the first thermocouple 24, and the second thermocouple 34 (if present) to pass therethrough. The ceramic shaft 36 is preferably made of the same ceramic material as the ceramic plate bonded body 12. The ceramic shaft 36 therefore preferably contains aluminum nitride or aluminum oxide, and more preferably aluminum nitride. The upper end surface of the ceramic shaft 36 is preferably bonded to the second surface 12e of the ceramic plate bonded body 12 by solid phase bonding or diffusion bonding. The outer diameter of the ceramic shaft 36 is not particularly limited, and is, for example, about 40 mm. The inner diameter of the ceramic shaft 36 (the diameter of the internal space S) is also not particularly limited, and is, for example, about 36 mm.

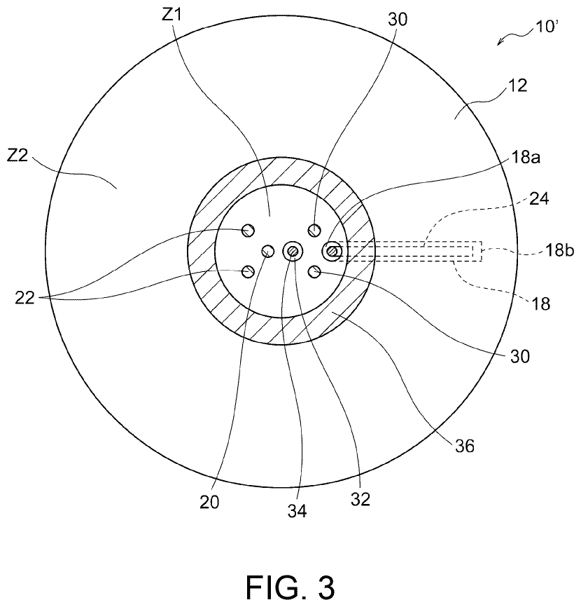

FIG. 3 shows a schematic plan view of the ceramic susceptor 10′ as viewed from the ceramic shaft 36 side. As shown in FIG. 3, the terminal rod 20, the power supply rods 22, the power supply rods 30, the thermocouple insertion hole 32, and the second thermocouple 34 are arranged in a region corresponding to the internal space S surrounded by the side wall of the ceramic shaft 36 as viewed from the ceramic shaft 36 side. The thermocouple insertion groove 18 and the first thermocouple 24 accommodated therein preferably extend linearly from the thermocouple insertion opening 18a in the region corresponding to the internal space S to the thermocouple insertion path end 18b at a predetermined position corresponding to the outer zone Z2 (preferably a position close to the outer circumference of the ceramic plate bonded body 12).

The ceramic plate bonded body 12 or the ceramic susceptor 10 and 10′ can be manufactured using a known method. For example, the ceramic plate bonded body 12 can be manufactured by applying a known ceramic adhesive to the surfaces to be bonded of the disk-shaped upper ceramic plate 12a and the disk-shaped lower ceramic plate 12b to bond them to each other, and then appropriately firing the plates, the disk-shaped upper ceramic plate 12a having the internal electrode 14 and the second heater circuit 26 embedded therein, the disk-shaped upper ceramic plate 12a having the thermocouple insertion groove 18 formed therein, the disk-shaped lower ceramic plate 12b having the first heater circuit 16 and the jumpers 28 embedded therein. Then, the obtained ceramic plate bonded body 12 can be processed to form a thermocouple insertion opening 18a, a thermocouple insertion hole 32, and other holes for inserting various rods, and the first thermocouple 24, the second thermocouple 34, and other various rods can be inserted or connected as necessary.

What is claimed is:

1. A ceramic susceptor comprising:
a disk-shaped ceramic plate bonded body including an upper ceramic plate and a lower ceramic plate bonded to each other at a bonding surface, the disk-shaped ceramic plate bonded body having a first surface opposite the bonding surface of the upper ceramic plate and a second surface opposite the bonding surface of the lower ceramic plate;
at least one internal electrode selected from the group consisting of an RF electrode and an ESC electrode, the internal electrode being embedded in the upper ceramic plate parallel to the first surface;
a first heater circuit embedded in the lower ceramic plate parallel to the first surface; and
a thermocouple insertion groove provided in the bonding surface side of the upper ceramic plate or the lower ceramic plate, the thermocouple insertion groove forming a thermocouple insertion path together with the bonding surface,
whereby the thermocouple insertion groove is arranged at a depth between the internal electrode and the first heater circuit in a thickness direction of the ceramic plate bonded body
wherein the ceramic susceptor further comprises a second heater circuit embedded in the upper ceramic plate parallel to the first surface, whereby the thermocouple insertion groove is arranged at a depth between the first heater circuit and the second heater circuit in the thickness direction of the ceramic plate bonded body.

2. The ceramic susceptor according to claim 1, wherein the second heater circuit is provided at a depth farther from the first surface than the internal electrode.

3. The ceramic susceptor according to claim 1, wherein when the ceramic plate bonded body is viewed in a plane, the ceramic plate bonded body includes an inner zone defined as a circular region within a predetermined distance from a center of the ceramic plate bonded body, and an outer zone defined as an annular region outside the inner zone, and
wherein the first heater circuit is arranged in the outer zone, and the second heater circuit is arranged in the inner zone.

4. The ceramic susceptor according to claim 3, further comprising a jumper embedded in the inner zone in the lower ceramic plate and connected to the first heater circuit, wherein power is suppliable to the first heater circuit through the jumper via a power supply rod, the power supply rod having one end connected to the jumper and another end extending from the second surface to an outside of the ceramic plate bonded body.

5. The ceramic susceptor according to claim 3, further comprising a thermocouple insertion hole composed of a vertical hole that penetrates the lower ceramic plate from the inner zone of the second surface to reach the upper ceramic plate.

6. The ceramic susceptor according to claim 5, wherein the thermocouple insertion hole reaches a depth closer to the first surface than the second heater circuit.

7. The ceramic susceptor according to claim 1, further comprising a cylindrical ceramic shaft attached to the second surface of the ceramic plate bonded body.

8. The ceramic susceptor according to claim 1, further comprising a first thermocouple for an outer zone, the first thermocouple being inserted into the thermocouple insertion path.

9. The ceramic susceptor according to claim 5, further comprising a second thermocouple for the inner zone, the second thermocouple being inserted into the thermocouple insertion hole.

10. The ceramic susceptor according to claim 9, wherein the ceramic susceptor further comprises a first thermocouple for an outer zone, the first thermocouple being inserted into the thermocouple insertion path and
wherein the second thermocouple reaches a depth closer to the first surface than the first thermocouple.
